(19) United States
(12) Patent Application Publication
(10) Pub. No.: US 2013/0134838 A1
(43) Pub. Date: May 30, 2013

(54) PIEZOELECTRIC MEMS TRANSFORMER

(71) Applicants: Changhan Hobie Yun, San Diego, CA (US); Chi Shun Lo, San Diego, CA (US); Chengjie Zuo, Santee, CA (US); Jonghae Kim, San Diego, CA (US)

(72) Inventors: Changhan Hobie Yun, San Diego, CA (US); Chi Shun Lo, San Diego, CA (US); Chengjie Zuo, Santee, CA (US); Jonghae Kim, San Diego, CA (US)

(73) Assignee: QUALCOMM MEMS TECHNOLOGIES, INC., San Diego, CA (US)

(21) Appl. No.: 13/305,293

(22) Filed: Nov. 28, 2011

(51) Int. Cl. H01L 41/107; H01L 41/22

(52) U.S. Cl. 310/366; 29/25.35

(57) ABSTRACT

This disclosure provides implementations of electromechanical systems piezoelectric resonator transformers, devices, apparatus, systems, and related processes. In one aspect, a transformer includes a piezoelectric layer; a first conductive layer arranged over a first surface of the piezoelectric layer including a first set of electrodes and a second set of electrodes interdigitated with the first set. The transformer includes a second conductive layer arranged over a second surface including at least a third set of electrodes. In some implementations, the transformer includes a first port capable of receiving an input signal and to which the first set of electrodes are coupled, and a second port capable of being coupled to a load and of outputting an output signal, the second set of electrodes being coupled to the second port. Generally, a ratio of the number of electrodes of the second set to the first set characterizes a transformation ratio.

### TECHNICAL FIELD

This disclosure relates generally to electromechanical systems (EMS) transformers, and more specifically to piezoelectric EMS resonators suitable for use as transformers.

### DESCRIPTION OF THE RELATED TECHNOLOGY

Electromechanical systems (EMS) include devices having electrical and mechanical elements, transducers such as actuators and sensors, optical components (including mirrors), and electronics. Electromechanical systems can be manufactured at a variety of scales including, but not limited to, microscales and nanoscales. For example, microelectromechanical systems (MEMS) devices can include structures having sizes ranging from about one micron to hundreds of microns or more. Nanoelectromechanical systems (NEMS) devices can include structures having sizes smaller than one micron including, for example, sizes smaller than several hundred nanometers. Electromechanical elements may be created using deposition, etching, lithography, and/or other micromachining processes that etch away parts of substrates and/or deposited material layers, or that add layers to form electrical, mechanical, and electromechanical devices.

One type of EMS device is called an interferometric modulator (IMOD). As used herein, the term IMOD or interferometric light modulator refers to a device that selectively absorbs and/or reflects light using the principles of optical interference. In some implementations, an IMOD may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the IMOD. IMOD devices have a wide range of applications, and are anticipated to be used in improving existing products and creating new products, especially those with display capabilities.

Various electronic circuit components can be implemented at the EMS level, including transformers. A transformer transfers electrical energy from one circuit to another through inductively-coupled coils. A varying current, Ip, in a primary coil induces a voltage, Vs, in a secondary coil. When a load is connected to the secondary coil, electrical energy can be transferred through the coils to the load. The induced voltage, Vs, in the second coil is generally proportional to a voltage, Vp, delivered to the first coil and is given by the ratio of the number of turns (windings) in the second coil, Ns, to the number of turns in the first coil, Np. This transformation ratio is generally defined as follows:

Vs/Vp=Ns/Np

In some modern circuits, small form factor transformers are specified. Conventional transformers made of relatively large metal spiral inductors often do not meet such specifications, especially as devices become increasingly smaller and power requirements become increasingly important.

### SUMMARY

The structures, devices, apparatus, systems, and processes of the disclosure each have several innovative aspects, no single one of which is solely responsible for the desirable attributes disclosed herein.

Disclosed are example implementations of piezoelectric electromechanical systems (EMS) resonator transformers, devices, apparatus, systems, and related fabrication processes.

According to one innovative aspect of the subject matter described in this disclosure, a piezoelectric transformer includes a piezoelectric layer and two conductive layers. The first conductive layer is arranged over a first surface of the piezoelectric layer and includes a first set of one or more electrodes and a second set of one or more electrodes. In some implementations, the first set is interdigitated with the second set. The piezoelectric transformer also includes a second conductive layer arranged over a second surface of the piezoelectric layer opposite the first surface that includes at least a third set of one or more electrodes. In some implementations, the piezoelectric transformer also includes a first port capable of receiving an input signal, the first set of electrodes being coupled to the first port; and a second port capable of being coupled to a load and capable of outputting an output signal, the second set of electrodes being coupled to the second port. In some implementations, a ratio of the number of electrodes of the second set to the number of electrodes of the first set characterizes a transformation ratio.

In some implementations, one or both of the first and second conductive layers further includes one or more floating electrodes interdigitated with at least ones of the electrodes of the first and second sets.

In some implementations, the piezoelectric transformer can be arranged, for example in series, with one or more other piezoelectric transformers to achieve a desired transformation ration and improved coupling efficiency and energy conversion.

According to another innovative aspect of the subject matter described in this disclosure, a piezoelectric transformer includes a piezoelectric layer and two conductive layers. The first conductive layer is arranged over a first surface of the piezoelectric layer and includes a first set of one or more electrodes and a second set of one or more electrodes. A second conductive layer is arranged over a second surface of the piezoelectric layer opposite the first surface and includes a third set of one or more electrodes and a fourth set of one or more electrodes. In some implementations, the first set of electrodes and the third set of electrodes are arranged in a first vertical arrangement, the first vertical arrangement including a number of first pairs, each first pair including an electrode from the first set and a corresponding electrode from the third set. In some implementations, the second set of electrodes and the fourth set of electrodes are arranged in a second vertical arrangement, the second arrangement including a number of second pairs, each second pair including an electrode from the second set and a corresponding electrode from the fourth set. In some such implementations, the first arrangement is interdigitated with the second arrangement and a ratio of the number of second pairs to the number of first pairs at least partially characterizes a transformation ratio.

In some implementations, the piezoelectric transformer further includes a first input port capable of receiving a first component of a differential input signal, the first set of electrodes being coupled to the first input port; a second input port capable of receiving a second component of the differential input signal, the third set of electrodes being coupled to the second input port; a first output port capable of being coupled to a load and capable of outputting a first component of a differential output signal, the second set of electrodes being coupled to the first output port; and a second output port capable of being coupled to the load and capable of outputting a second component of the differential output signal, the fourth set of electrodes being coupled to the second output port.

In some implementations, one or both of the first and second conductive layers further includes one or more floating electrodes interdigitated with at least ones of the electrodes of the first and second sets.

In some implementations, the piezoelectric transformer can be arranged, for example in series, with one or more other piezoelectric transformers to achieve a desired transformation ration and improved coupling efficiency and energy conversion.

In some implementations, the piezoelectric transformer further includes a fifth set of electrodes in the first conductive layer and a sixth set of electrodes in the second conductive layer. In some such implementations, the fifth set of electrodes and the sixth set of electrodes are arranged in a third arrangement, the third arrangement including a number of third pairs, each third pair comprising an electrode from the fifth set and a corresponding electrode from the sixth set. In some implementations, the third arrangement is interdigitated with the first and second arrangements and a ratio of the sum of the number of second pairs and the number of third pairs to the number of first pairs characterizes an effective transformation ratio. In some such implementations, the piezoelectric transformer also includes a first input port capable of receiving a differential input signal, the first set of electrodes being coupled to the first input port; a second input port capable of receiving the differential input signal, the sixth set of electrodes being coupled to the second input port; a first output port capable of being coupled to a load and capable of outputting an output signal, the second set of electrodes being coupled to the first output port; and one or more ground ports, each of the second set of electrodes, the fifth set of electrodes, and the fourth set of electrodes being coupled to one or more of the ground ports.

According to another innovative aspect of the subject matter described in this disclosure, a piezoelectric transformer includes a first piezoelectric resonator and a second piezoelectric resonator. The first piezoelectric resonator includes an upper conductive layer, a lower conductive layer, and a piezoelectric layer disposed between the upper conductive layer and the lower conductive layer. One or more of the conductive layers includes a plurality of input electrodes and one or more output electrodes, the input electrodes coupled to an input port capable of receiving a differential signal, the one or more output electrodes coupled to a connection port. Similarly, the second resonator includes an upper conductive layer, a lower conductive layer, and a piezoelectric layer disposed between the upper conductive layer and the lower conductive layer of the second resonator. One or more of the conductive layers of the second resonator includes a plurality of input electrodes and one or more output electrodes, the input electrodes of the second resonator coupled to the connection port, the one or more output electrodes of the second resonator coupled to an output port capable of being coupled to a load. In some implementations, a number of the output electrodes of the second resonator in relation to a number of the input electrodes of the first resonator defines a transformation ratio.

According to another innovative aspect of the subject matter described in this disclosure, a process for forming a resonator structure includes forming a lower conductive layer of electrodes; forming a piezoelectric layer over the lower electrode layer; and forming an upper conductive layer of electrodes over the piezoelectric layer.

In some implementations, the upper conductive layer includes at least a first set of one or more electrodes and a second set of one or more electrodes, the first set being interdigitated with the second set. In some such implementations, the lower conductive layer includes at least a third set of one or more electrodes. In some implementations, a ratio of the number of electrodes of the second set to the number of electrodes of the first set characterizes a transformation ratio.

In some implementations, the lower conductive layer further includes a fourth set of one or more electrodes. In some such implementations, the first set of electrodes and the third set of electrodes are arranged in a first arrangement, the first arrangement including a number of first pairs, each first pair including an electrode from the first set and a corresponding electrode from the third set. In some such implementations, the second set of electrodes and the fourth set of electrodes are arranged in a second arrangement, the second arrangement including a number of second pairs, each second pair including an electrode from the second set and a corresponding electrode from the fourth set. In some implementations, the first arrangement is interdigitated with the second arrangement and a ratio of the number of second pairs to the number of first pairs at least partially characterizes a transformation ratio.

In some other implementations, the upper conductive layer further includes a fifth set of electrodes and the lower conductive layer further includes a sixth set of electrodes. In some such implementations, the fifth set of electrodes and the sixth set of electrodes are arranged in a third arrangement, the third arrangement including a number of third pairs, each third pair comprising an electrode from the fifth set and a corresponding electrode from the sixth set. In some implementations, the third arrangement is interdigitated with the first and second arrangements and a ratio of the sum of the number of second pairs and the number of third pairs to the number of first pairs characterizes an effective transformation ratio.

According to another innovative aspect of the subject matter described in this disclosure, a piezoelectric transformer includes piezoelectric means including piezoelectric material; first conductive means arranged over a first surface of the piezoelectric material and including a first set of one or more electrodes and a second set of one or more electrodes, the first set being interdigitated with the second set; second conductive means arranged over a second surface of the piezoelectric material opposite the first surface and including at least a third set of one or more electrodes. In some implementations, the piezoelectric transformer also includes first coupling means capable of receiving an input signal, the first set of electrodes being coupled to the first coupling means; and second coupling means capable of being coupled to a load and capable of outputting an output signal, the second set of electrodes being coupled to the second coupling means. In some implementations, a ratio of the number of electrodes of the second set to the number of electrodes of the first set characterizes a transformation ratio.

Details of one or more implementations of the subject matter described in this specification are set forth in the accompanying drawings and the description below. Although the examples provided in this disclosure are primarily described in terms of electromechanical systems (EMS) and microelectromechanical systems (MEMS)-based displays, the concepts provided herein may apply to other types of displays, such as liquid crystal displays, organic light-emitting diode (“OLED”) displays and field emission displays. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows a cross-sectional side view of an example piezoelectric transformer.

FIG. 2 shows a top view of the example piezoelectric transformer of FIG. 1.

FIGS. 3-5 show top views of example piezoelectric transformers.

FIG. 6 shows a top view of an example piezoelectric transformer arrangement that includes three piezoelectric transformers.

FIG. 7 shows a cross-sectional side view of another piezoelectric transformer that uses a differential drive scheme.

FIGS. 8A and 8B show top and bottom views, respectively, of an example piezoelectric transformer arrangement that uses a differential drive scheme.

FIG. 9 shows a cross-sectional side view of another example piezoelectric transformer.

FIG. 10 shows a perspective cross-sectional view of an example piezoelectric transformer supported in a cavity.

FIG. 11 shows a flow diagram illustrating an example process for forming an example piezoelectric transformer.

FIG. 12A shows an isometric view depicting two adjacent example pixels in a series of pixels of an example interferometric modulator (IMOD) display device.

FIG. 12B shows an example system block diagram illustrating an example electronic device incorporating an IMOD display.

FIGS. 13A and 13B show examples of system block diagrams illustrating an example display device that includes a plurality of IMODs.

Like reference numbers and designations in the various drawings indicate like elements.

### DETAILED DESCRIPTION

The following detailed description is directed to certain implementations for the purposes of describing the innovative aspects. However, the teachings herein can be applied and implemented in a multitude of different ways.

The disclosed implementations include examples of structures and configurations of electromechanical systems (EMS) resonator devices, including piezoelectric EMS resonator transformers. Related apparatus, systems, and fabrication processes and techniques are also disclosed. In the disclosed implementations of piezoelectric EMS resonator transformers (hereinafter “piezoelectric transformer”), electrodes are disposed in contact with or in proximity to a piezoelectric material. For instance, the electrodes can be located on the same surface or on opposite surfaces of a layer of the piezoelectric material.

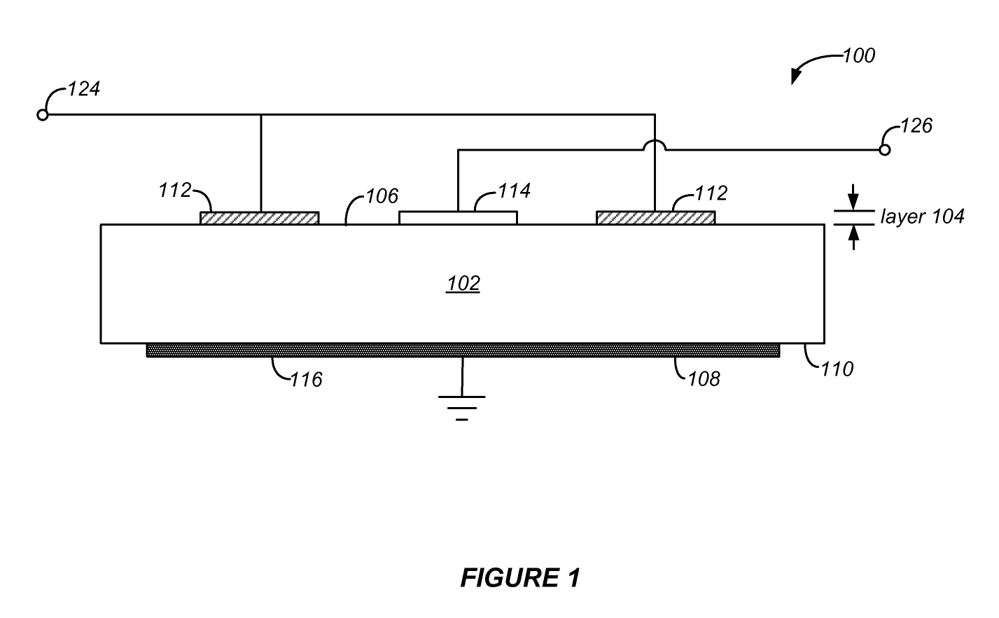

FIG. 1 illustrates a cross-sectional side view of an example piezoelectric transformer 100 that includes a piezoelectric layer 102, a first (upper) conductive layer 104 arranged over a first (upper) surface 106 of the piezoelectric layer 102 and a second (lower) conductive layer 108 arranged over a second (lower) surface 110 of the piezoelectric layer 102 opposite the first surface. In some implementations, the first conductive layer 104 includes a first set of one or more first electrodes 112 and a second set of one or more second electrodes 114. In some such implementations, the first electrodes 112 are interdigitated with the second electrodes 114. In some implementations, the second conductive layer 108 includes at least a third set of one or more third electrodes 116.

Piezoelectric transformer 100 also includes a first port 124 capable of receiving an input signal, such as a varying input signal. The first electrodes 112 are coupled to the first port 124. Piezoelectric transformer 100 also includes a second port 126 that can be coupled to a load and capable of outputting an output signal. The second electrodes 114 are coupled to the second port 126. In some such implementations, a ratio of the number of second electrodes 114 to the number of first electrodes 112 characterizes an effective transformation ratio of the piezoelectric transformer 100. In some implementations, the transformation ratio is related to the impedance ratio of the output impedance measurable at the second port 126 to the input impedance measurable at the first port 124. For reference, the transformation ratio is a characteristic that is more general than the impedance ratio. Depending on the source impedance or load impedance, the transformation ratio for a signal (voltage or current) may be equal or not to the impedance ratio of the transformer.

An electric field applied via the input signal between first electrodes 112 and third electrodes 116 is transduced into a mechanical strain in the piezoelectric material layer 102. For instance, a time-varying electrical signal can be provided to the first electrodes 112 of the transformer 100 and transduced to a corresponding time-varying mechanical motion. A portion of this mechanical energy can be transferred back to electrical energy at the second electrodes 114 and output over the second port 126. The frequencies of the input electrical signal that produce the greatest substantial amplifications of the mechanical displacement in the piezoelectric material are generally referred to as resonant frequencies.

Particular implementations of the subject matter described in this disclosure can be implemented to realize one or more of the following potential advantages. The disclosed piezoelectric resonators can function as EMS transformers suitable for applications for which conventional wire inductor transformers are no longer feasible. Some examples of the disclosed piezoelectric transformers provide the advantages of compact size, such as on the order of 1 μm (micrometer) to 100 μm in length and/or width, low insertion loss, low power consumption, and compatibility with high-yield mass-producible components.

Some implementations described herein are based on a contour mode resonator configuration. In such implementations, the resonant frequency of a CMR can be substantially controlled by engineering the lateral (e.g., length and width) dimensions of the piezoelectric material layers and the electrode layers as well as engineering the periodicity of the electrodes and the thickness of the piezoelectric layer. One benefit of such a construction is that multi-frequency RF filters, clock oscillators, transformers, transducers or other devices, each including one or more CMRs depending on the desired implementation, can be fabricated on the same substrate. For example, this may be advantageous in terms of cost and size by enabling compact, multi-band filter solutions for RF front-end applications on a single chip. In some examples, by co-fabricating multiple CMRs with different finger widths, as described in greater detail below, multiple frequencies can be addressed on the same die. In some examples, arrays of CMRs with different frequencies spanning a range from MHz to GHz can be fabricated on the same substrate.

In one or more implementations, the piezoelectric resonator transformer structure is suspended in a cavity of a supporting structure. The piezoelectric resonator transformer of the piezoelectric transformer can be suspended in the cavity by specially designed tethers coupling the piezoelectric transformer to the supporting structure, as further explained below. These tethers are often fabricated in the layer stack of the piezoelectric resonator transformer itself. The piezoelectric resonator transformer can be acoustically isolated from the surrounding structural support and other apparatus by virtue of the cavity.

The disclosed piezoelectric transformers can be fabricated on a low-cost, high-performance, large-area insulating substrate, which, in some implementations, forms at least a portion of the supporting structure described herein. In some implementations, the insulating substrate on which the disclosed piezoelectric transformers are formed can be made of display-grade glass (alkaline earth boro-aluminosilicate) or soda lime glass. Other suitable insulating materials of which the insulating substrate can be made include silicate glasses, such as alkaline earth aluminosilicate, borosilicate, modified borosilicate, and others. Also, ceramic materials such as aluminum oxide (AlOx), yttrium oxide (Y₂O₃), boron nitride (BN), silicon carbide (SiC), aluminum nitride (AlNx), and gallium nitride (GaNx) can be used as the insulating substrate material. In some other implementations, the insulating substrate is formed of high-resistivity silicon. In some implementations, silicon On Insulator (SOI) substrates, gallium arsenide (GaAs) substrates, indium phosphide (InP) substrates, and plastic (polyethylene naphthalate or polyethylene terephthalate) substrates, e.g., associated with flexible electronics, also can be used. The substrate can be in conventional Integrated Circuit (IC) wafer form, e.g., 4-inch, 6-inch, 8-inch, 12-inch, or in large-area panel form. For example, flat panel display substrates with dimensions such as 370 mm×470 mm, 920 mm×730 mm, and 2850 mm×3050 mm, can be used.

In some implementations, the disclosed piezoelectric transformers are fabricated by depositing a sacrificial (SAC) layer on the substrate; forming one or more lower conductive electrode layers on the SAC layer; depositing a piezoelectric layer on the lower conductive electrode layer; forming one or more upper electrode layers on the piezoelectric layer; and removing at least part of the SAC layer to define a cavity. The resulting resonator cavity separates at least a portion of the lower electrode layer from the substrate and provides openings along the sides of the piezoelectric resonator transformer, as illustrated in the accompanying figures, to allow the resonator to vibrate and move in one or more directions with substantial elastic isolation from the remaining substrate. In some other implementations, a portion of the substrate itself serves as a SAC material. In these implementations, designated regions of the insulating substrate below the piezoelectric resonator transformer can be removed, for example, by etching to define the cavity.

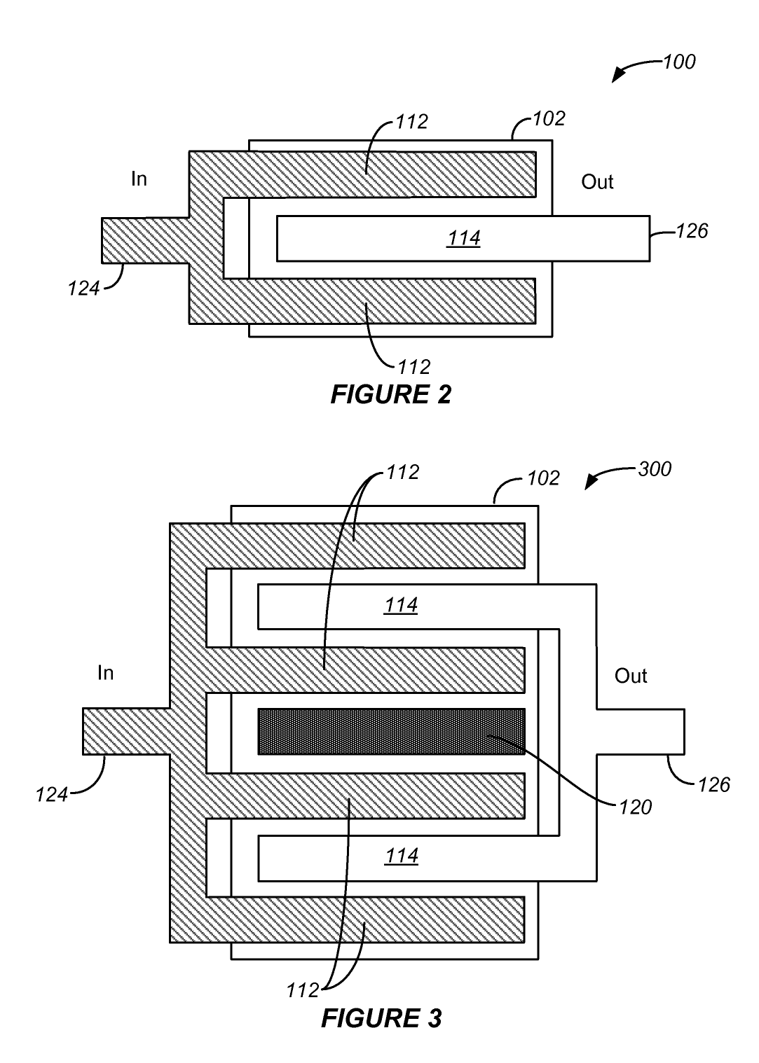

FIG. 2 illustrates a top view of an example implementation of the piezoelectric transformer 100 of FIG. 1 in which the ratio of the number of second electrodes 114 to the number of first electrodes 112 (hereinafter the “transformation ratio”) is 1:2. In the implementation of FIG. 2, the piezoelectric transformer 100 includes one second electrode 114 and two first electrodes 112. The second electrode 114 is arranged between the first electrodes 112.

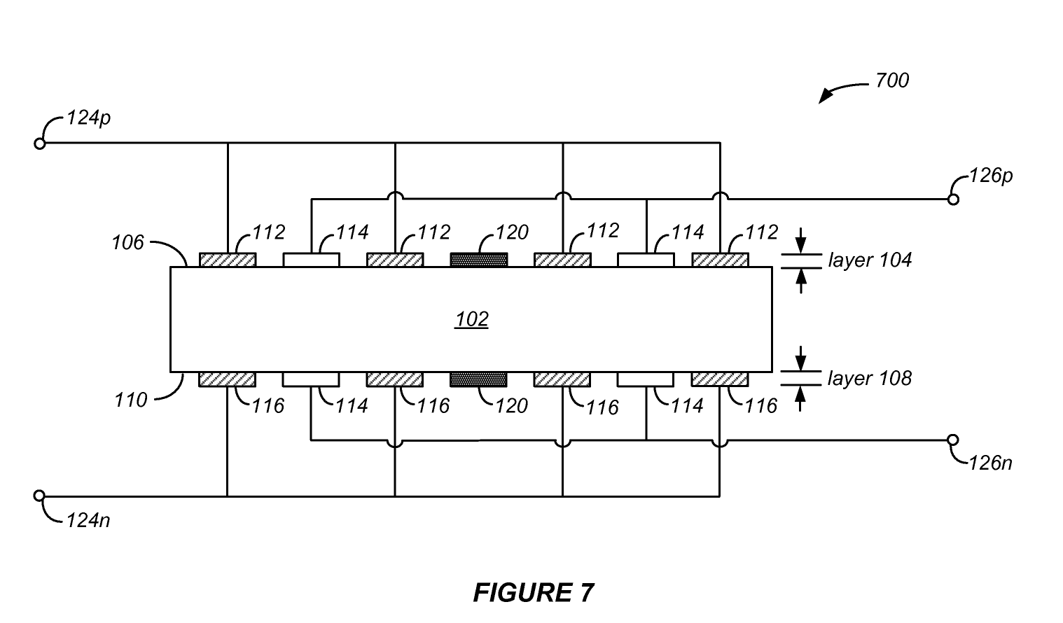

In some implementations, the one or more third electrodes 116 in the implementations described with reference to FIGS. 1 and 2, as well as in some implementations described with reference to other Figures below, can be coupled to ground. In other implementations, the third electrodes 116 can be driven with a varying input signal, as described with reference to FIG. 7. In some implementations, the one or more third electrodes 116 include only a single conductive plane 116. In other implementations, the third electrodes 116 can be arranged in a similar pattern to the first and second electrodes 112 and 114. For example, the third electrodes 116 can include a third electrode 116 arranged opposite each of the first electrodes 112 and each of the second electrodes 114.

FIG. 3 illustrates a top view of an example implementation of a piezoelectric transformer 300 in which the transformation ratio (the number of second electrodes 114 to the number of first electrodes 112) is 1:2. In the implementation of FIG. 3, the piezoelectric transformer 300 includes two second electrodes 114 and four first electrodes 112. The second electrodes 114 are interdigitated with the first electrodes; that is, for example, the second electrodes 114 are arranged between the first electrodes 112 in an alternating fashion as shown in FIG. 3. In the example of FIG. 3, the second electrodes 114 are interdigitated with the first electrodes 112 such that each second electrode 114 is arranged between two adjacent first electrodes 112.

Piezoelectric transformer 300 also includes a first port 124 capable of receiving a input signal. The first electrodes 112 are coupled to the first port 124. Piezoelectric transformer 300 also can include a second port 126 that can be coupled to a load and capable of outputting an output signal. The second electrodes 114 are coupled to the second port 126.

In some implementations, the first and second ports 124 and 126, or the signals routed through them, can be reversed. For example, in FIG. 3 the first port 124 receives an input signal and second port 126 transmits an output signal. In another implementation, second port 126 can receive the input signal and first port 124 can transmit the output signal. In such an implementation, the transformation ratio would be 2:1 rather than 1:2. The switching of the first and second ports, or the signals traversing them, can be switched in any of the implementations described or disclosed herein.

In some implementations, one or both of the first conductive layer 104 and the second conductive layer 108 also includes one or more floating electrodes interdigitated with ones of the first electrodes 112, second electrodes 114 or third electrodes 116. In FIG. 3, the first conductive layer 104 of the example piezoelectric transformer 300 includes a floating electrode 120 arranged between the middle two first electrodes 112, as shown.

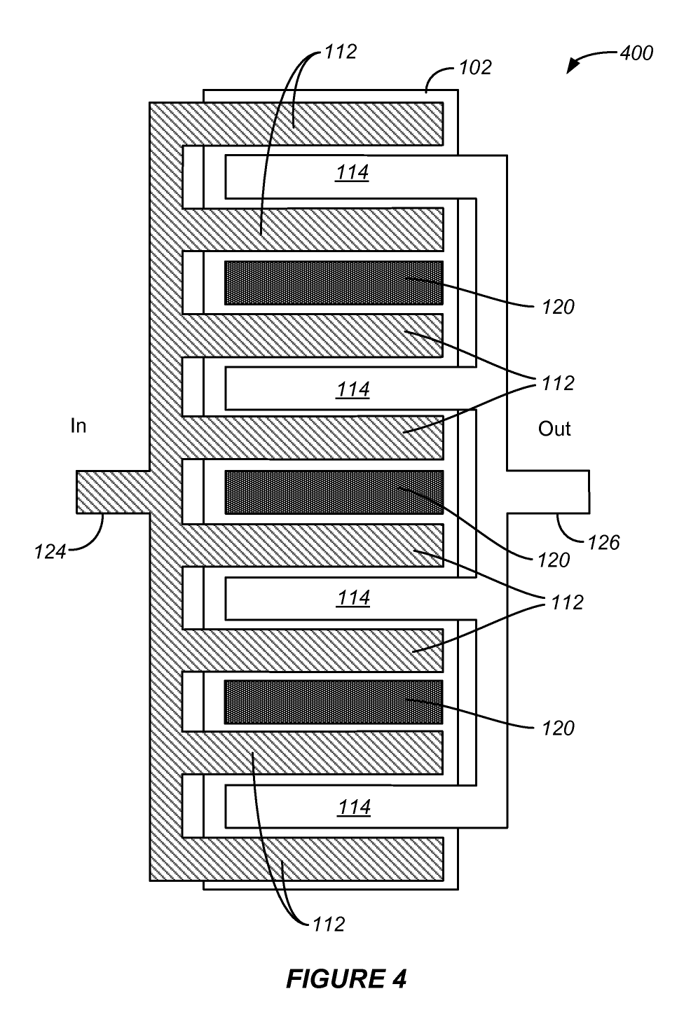

FIG. 4 illustrates a top view of an example implementation of a piezoelectric transformer 400 in which the transformation ratio (the number of second electrodes 114 to the number of first electrodes 112) is 1:2. In the implementation of FIG. 4, the piezoelectric transformer 400 includes four second electrodes 114 and eight first electrodes 112. The second electrodes 114 are interdigitated with the first electrodes; that is, for example, the second electrodes 114 are arranged between the first electrodes 112 in an alternating fashion as shown in FIG. 4. In the example of FIG. 4, the second electrodes 114 are interdigitated with the first electrodes 112 such that each second electrode 114 is arranged between two adjacent first electrodes 112.

Piezoelectric transformer 400 also includes a first port 124 capable of receiving an input signal. The first electrodes 112 are coupled to the first port 124. Piezoelectric transformer 400 also can include a second port 126 that can be coupled to a load and capable of outputting an output signal. The second electrodes 114 are coupled to the second port 126. In FIG. 4, the first conductive layer 104 of the example piezoelectric transformer 400 also includes floating electrodes 120 each arranged between other ones of the adjacent first electrodes 112 not separated by a second electrode 114.

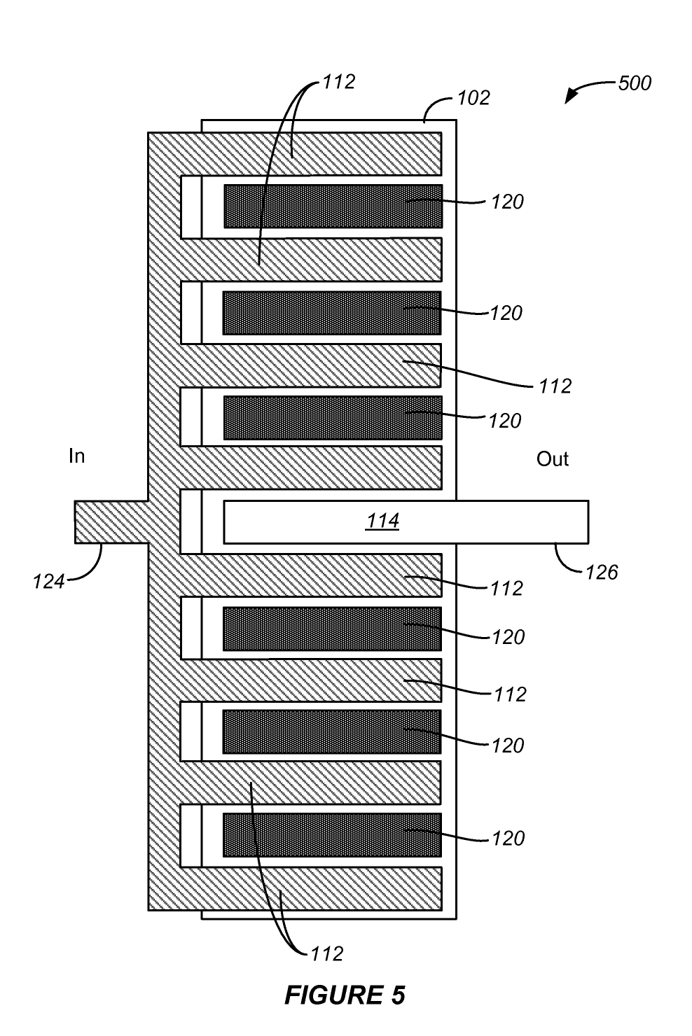

FIG. 5 illustrates a top view of an example implementation of a piezoelectric transformer 500 in which the transformation ratio (the number of second electrodes 114 to the number of first electrodes 112) is 1:8. In the implementation of FIG. 5, the piezoelectric transformer 500 includes one second electrode 114 and eight first electrodes 112. In such an implementation, the second electrode 114 can be arranged between the middle-two first electrodes 112 as shown in FIG. 5. In some implementations, one or both of the first conductive layer 104 and the second conductive layer 108 also includes one or more floating electrodes interdigitated with ones of the first electrodes 112, second electrode 114 or third electrodes 116.

The piezoelectric transformer 500 also includes a first port 124 capable of receiving an input signal. The first electrodes 112 are coupled to the first port 124. Piezoelectric transformer 500 also can include a second port 126 that can be coupled to a load and capable of outputting an output signal. The second electrodes 114 are coupled to the second port 126. In FIG. 5, the first conductive layer 104 of the example piezoelectric transformer 500 also includes floating electrodes 120 each arranged between other ones of the adjacent first electrodes 112 not separated by the second electrode 114.

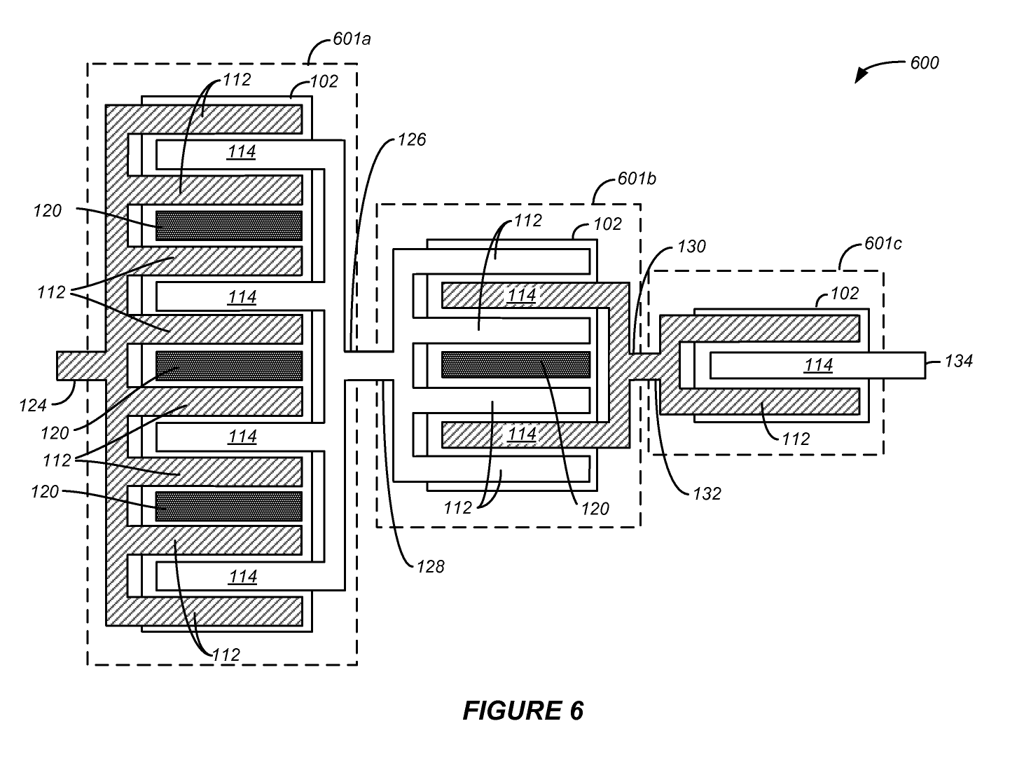

In other implementations, two or more piezoelectric transformers can be connected, for example, in series, to achieve higher efficiency energy conversion. For example, FIG. 6 illustrates a top view of an example implementation of a piezoelectric transformer arrangement 600 that also has an effective transformation ratio of about 1:8 like the implementation of FIG. 5, but which achieves a significantly higher efficiency energy conversion than that achievable with the implementation of FIG. 5. In the illustrated implementation, piezoelectric transformer arrangement 600 includes a first piezoelectric transformer 601a (such as piezoelectric transformer 400 shown in FIG. 4) coupled with a second piezoelectric transformer 601b (such as piezoelectric transformer 300 shown in FIG. 3), which is coupled to a third piezoelectric transformer 601c (such as piezoelectric transformer 100 shown in FIGS. 1 and 2). The piezoelectric transformer arrangement 600 of FIG. 6, although having a combined effective transformation ratio of 1:8 like the piezoelectric transformer of FIG. 5, achieves higher efficiency at least in part because each of piezoelectric transformers 601a-601c individually achieves high efficiency because each of piezoelectric transformers 601a-601c individually has a transformation ratio of 1:2.

In general, the closer the transformation ratio is to 1:1, the higher the possible efficiency. On the other hand, if the transformer has fewer floating electrodes 120, the transformer can have higher electromechanical coupling or higher transformation efficiency. For example, simply because there is mechanical strain existing in all the fingers of the resonator, the energy of those fingers with floating electrodes is wasted if not collected by the output electrode.

In the illustrated implementation, piezoelectric transformer 601a includes a first port 124 capable of receiving an input signal. The first electrodes 112 of piezoelectric transformer 601a are coupled to the first port 124. Piezoelectric transformer 601a also includes a second port 126 capable of outputting a first output signal and to which the second electrodes 114 of piezoelectric transformer 601a are coupled. In the illustrated implementation, piezoelectric transformer 601b includes a first port 128 capable of receiving the first output signal. The first electrodes 112 of piezoelectric transformer 601b are coupled to the first port 128. Piezoelectric transformer 601b also includes a second port 130 capable of outputting a second output signal and to which the second electrodes 114 of piezoelectric transformer 601b are coupled. In the illustrated implementation, piezoelectric transformer 601c includes a first port 132 capable of receiving the second output signal. The first electrodes 112 of piezoelectric transformer 601c are coupled to the first port 132. Piezoelectric transformer 601c also includes a second port 134 capable of outputting a third output signal and to which the second electrodes 114 of piezoelectric transformer 601c are coupled.

FIG. 7 illustrates a cross-sectional side view of another example piezoelectric transformer 700 that operates according to a different differential drive and sense scheme. Piezoelectric transformer 700 includes a piezoelectric layer 102, a first (upper) conductive layer 104 arranged over a first (upper) surface 106 of the piezoelectric layer 102 and a second (lower) conductive layer 108 arranged over a second (lower) surface 110 of the piezoelectric layer 102 opposite the first surface. In some implementations, the first conductive layer 104 includes a first set of one or more first electrodes 112 and a second set of one or more second electrodes 114. In some such implementations, the first electrodes 112 are interdigitated with the second electrodes 114. In various implementations, each of the piezoelectric transformers 100, 300, 400, and 500 can be implemented with a similar drive scheme to that which will now be described, but for didactic purposes, a piezoelectric transformer having first electrodes 112 and second electrodes 114 as arranged in FIG. 3 will be described.

In some implementations, the second conductive layer 108 includes a third set of one or more third electrodes 116 and a fourth set of one or more fourth electrodes 118. In FIG. 7, each of the third electrodes 116 is arranged opposite a corresponding one of the first electrodes 112 while each of the fourth electrodes 118 is arranged opposite a corresponding one of the second electrodes 114.

In the implementation of FIG. 7, piezoelectric transformer 700 includes a first input port 124p capable of receiving a first component of a differential input signal. The first electrodes 112 are coupled to the first input port 124p. Piezoelectric transformer 700 also includes a second input port 124n capable of receiving a second component of the differential input signal. The third electrodes 116 are coupled to the second input port 124n. In FIG. 7, piezoelectric transformer 700 also includes a first output port 126p capable of being coupled to a load and capable of outputting a first component of a differential output signal. The second electrodes 114 are coupled to the first output port 126p. Piezoelectric transformer 700 also can include a second output port 126n capable of being coupled to the load and capable of outputting a second component of the differential output signal. The fourth electrodes 118 are coupled to the second output port 126n.

Like other implementations described above, the piezoelectric transformer 700 also can include one or more floating electrodes in one or both of the first conductive layer 104 and the second conductive layer 108.

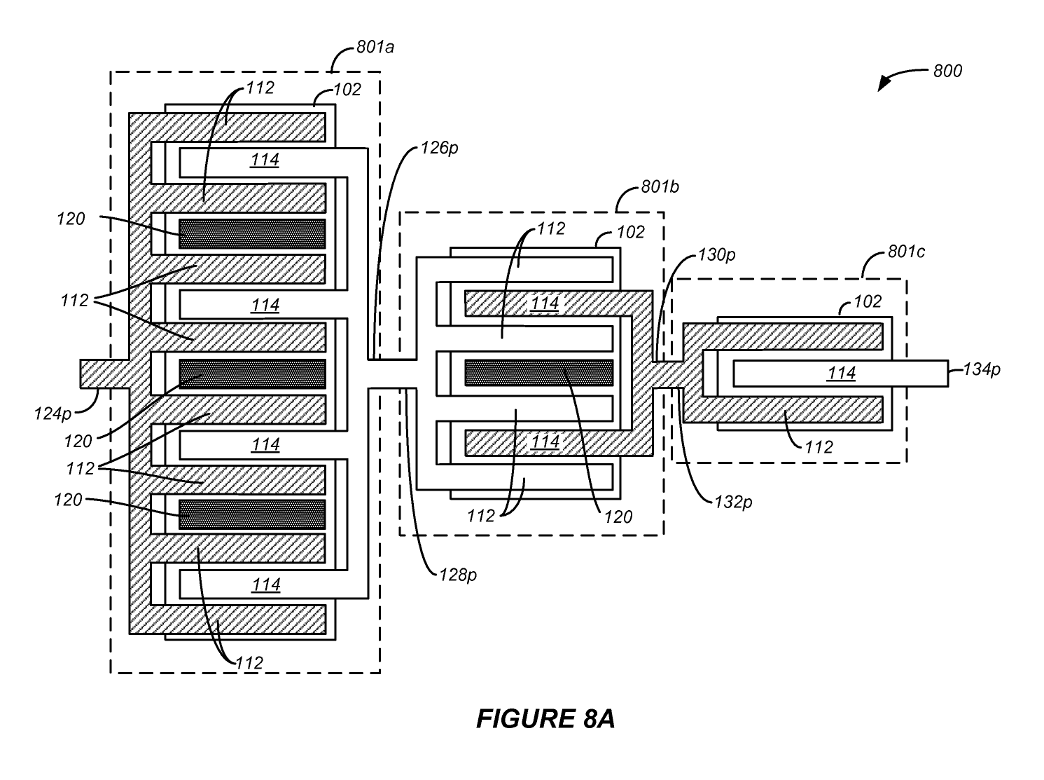

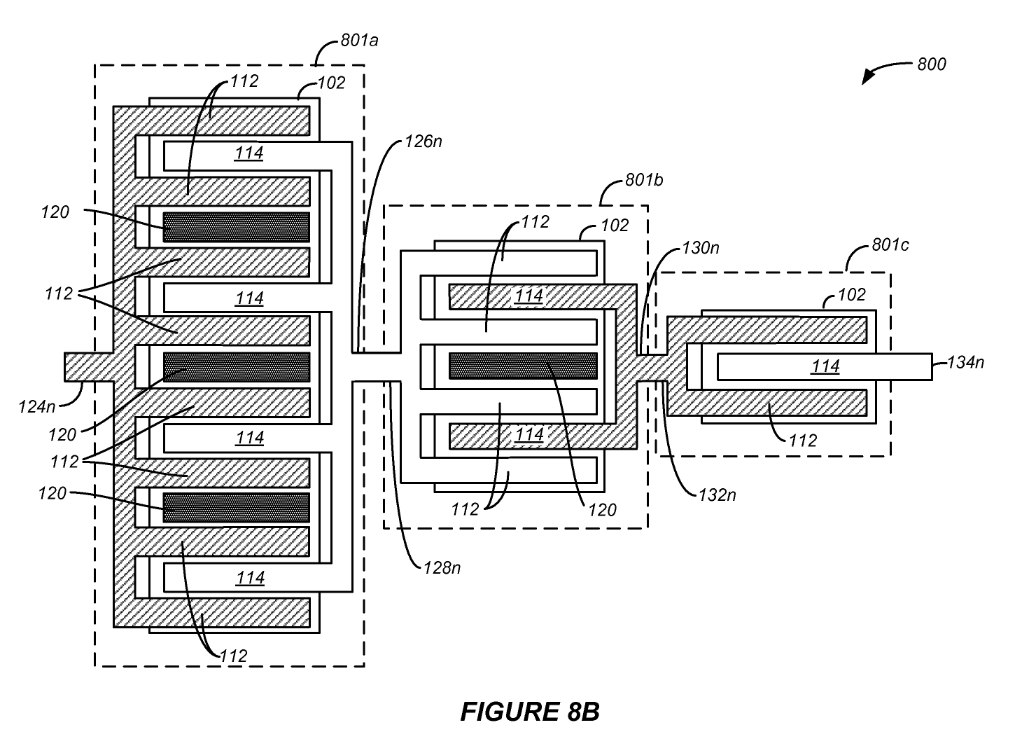

FIGS. 8A and 8B show top and bottom views, respectively, of another example piezoelectric arrangement 800 in which two or more piezoelectric transformers can be connected, for example, in series, to achieve higher efficiency energy conversion. For example, FIG. 8A illustrates a top view of an example implementation of a piezoelectric transformer arrangement 800 that also has an effective transformation ratio of about 1:8 like the implementation of FIG. 5, but which achieves a significantly higher efficiency energy conversion that that achievable with the implementation of FIG. 5. In the illustrated implementation, piezoelectric transformer arrangement 800 includes a first piezoelectric transformer 801a coupled with a second piezoelectric transformer 801b (such as piezoelectric transformer 700 shown in FIG. 7), which is coupled to a third piezoelectric transformer 801c. The piezoelectric transformer arrangement 800 of FIGS. 8A and 8B, although having a combined effective transformation ratio of 1:8 like the piezoelectric transformer of FIG. 5, achieves higher efficiency at least in part because each of piezoelectric transformers 801a-801c individually achieves high efficiency because each of piezoelectric transformers 801a-801c individually has a transformation ratio of 1:2.

In the arrangement of FIGS. 8A and 8B, the first piezoelectric transformer 801a includes a first input port 124p capable of receiving a first component of a differential input signal. The first electrodes 112 of piezoelectric transformer 801a are coupled to the first input port 124p. Piezoelectric transformer 801a includes a second input port 124n capable of receiving a second component of the differential input signal. The third electrodes 116 of piezoelectric transformer 801a are coupled to the second input port 124n. Piezoelectric transformer 801a also includes a first output port 126p capable of outputting a first component of a first differential output signal and to which the second electrodes 114 of piezoelectric transformer 801a are coupled. Piezoelectric transformer 801a also includes a second output port 126n capable of outputting a second component of the first differential output signal and to which the fourth electrodes 114 of piezoelectric transformer 801a are coupled.

In the illustrated implementation, the second piezoelectric transformer 801b includes a third input port 128p capable of receiving a first component of the first differential output signal. The first electrodes 112 of piezoelectric transformer 801b are coupled to the third input port 128p. Piezoelectric transformer 801b includes a fourth input port 128n capable of receiving a second component of the first differential output signal. The third electrodes 116 of piezoelectric transformer 801b are coupled to the fourth input port 128n. Piezoelectric transformer 801b also includes a third output port 130p capable of outputting a first component of a second differential output signal and to which the second electrodes 114 of piezoelectric transformer 801b are coupled. Piezoelectric transformer 801b also includes a fourth output port 130n capable of outputting a second component of the second differential output signal and to which the fourth electrodes 114 of piezoelectric transformer 801b are coupled.

In the illustrated implementation, the third piezoelectric transformer 801c includes a fifth input port 132p capable of receiving a first component of the second differential output signal. The first electrodes 112 of piezoelectric transformer 801c are coupled to the third input port 132p. Piezoelectric transformer 801c includes a sixth input port 132n capable of receiving a second component of the second differential output signal. The third electrodes 116 of piezoelectric transformer 801c are coupled to the sixth input port 132n. Piezoelectric transformer 801c also includes a fifth output port 134p capable of outputting a first component of a third differential output signal and to which the second electrodes 114 of piezoelectric transformer 801c are coupled. Piezoelectric transformer 801c also includes a sixth output port 134n capable of outputting a second component of the third differential output signal and to which the fourth electrodes 114 of piezoelectric transformer 801c are coupled.

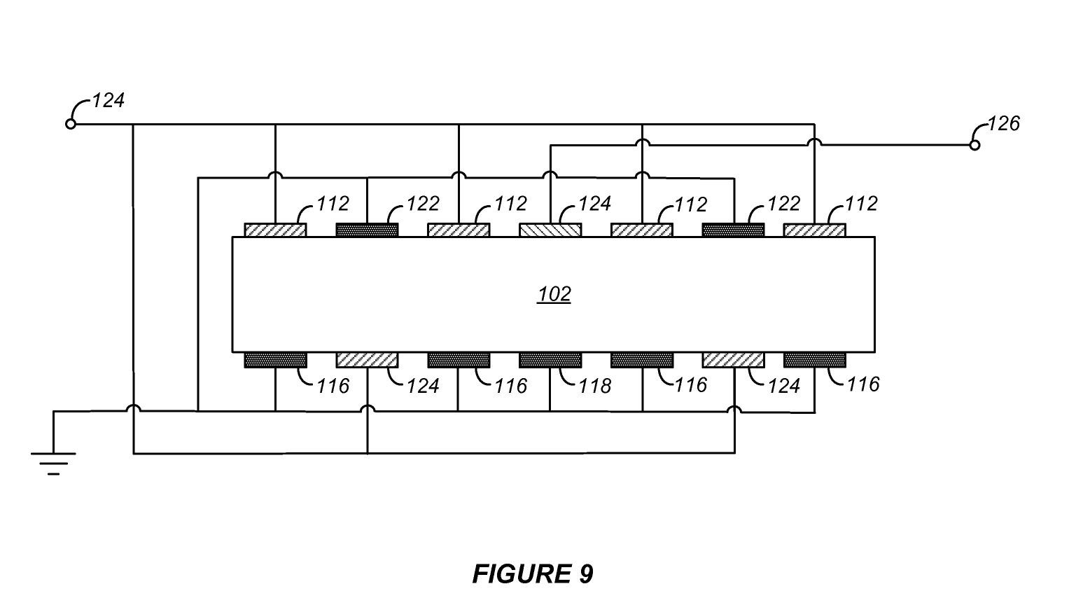

FIG. 9 illustrates a cross-sectional side view of another example piezoelectric transformer 900 that operates according to a different single-ended drive and sense scheme. Piezoelectric transformer 900 includes a piezoelectric layer 102, a first (upper) conductive layer 104 arranged over a first (upper) surface 106 of the piezoelectric layer 102 and a second (lower) conductive layer 108 arranged over a second (lower) surface 110 of the piezoelectric layer 102 opposite the first surface. The first conductive layer 104 includes a first set of one or more first electrodes 112, a second set of one or more second electrodes 114, and a fifth set of one or more fifth electrodes 122. The second conductive layer 108 includes a third set of one or more third electrodes 116, a fourth set of one or more fourth electrodes 118, and a sixth set of one or more sixth electrodes 124.

Piezoelectric transformer 900 also includes a first port 124 capable of receiving an input signal. The first electrodes 112 and sixth electrodes 124 are coupled to the first port 124. Piezoelectric transformer 900 also includes a second port 126 that can be coupled to a load and capable of outputting an output signal. The second electrodes 114 are coupled to the second port 126. In some such implementations, the third electrodes 116, the fourth electrodes 118, and the fifth electrodes 122 are coupled to ground.

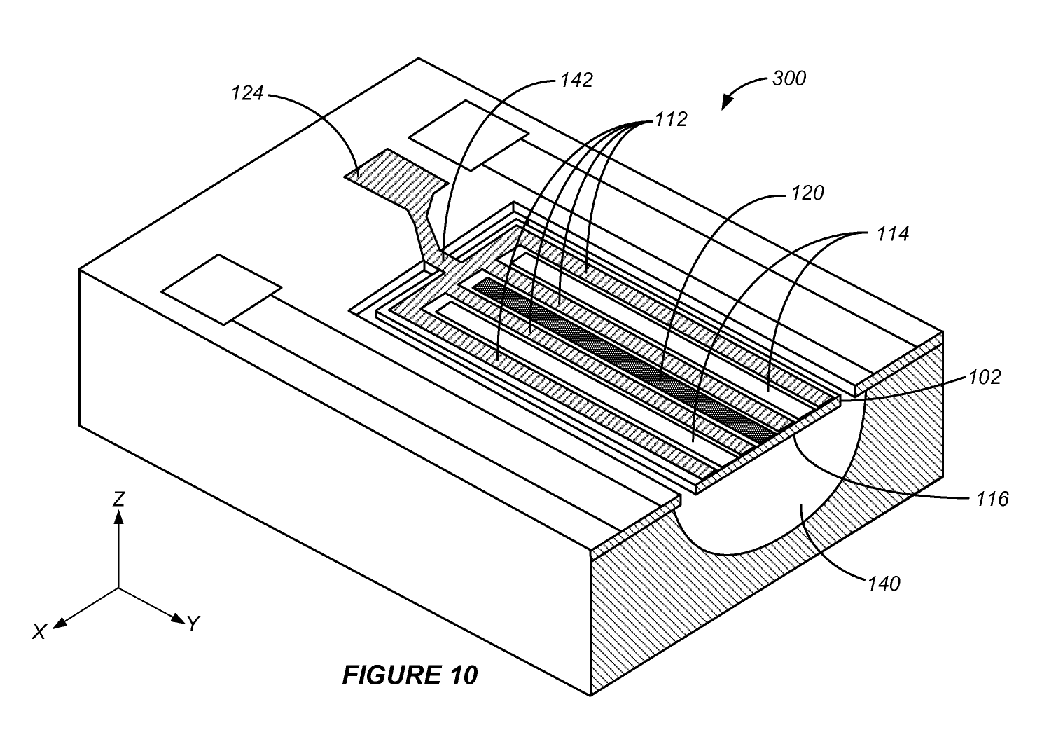

FIG. 10 shows a perspective cross-sectional view of an example piezoelectric resonator transformer, such as that shown in FIG. 3. In FIG. 10, piezoelectric resonator transformer 300 is suspended in a cavity 140 by virtue of a first tether, including tether interconnect 142 as well as a matching second tether (not shown) connected at the opposite end. In FIG. 10, the tethers serve as physical anchors to hold the transformer in the cavity 140. The piezoelectric resonator transformer is capable of vibration by virtue of the piezoelectric material layers 102.

Some implementations disclosed herein with reference to FIGS. 1-10 have been described using examples in which the transformation ratios were 1:2 or 1:8, or their complements, 2:1 and 8:1, respectively. In other implementations considered for the applications described herein or for other applications, the transformation ratios can be different than 1:2 or 1:8. For example, the transformation ratios can be 1:3, 2:5, 3:7, 5:8 or other desired ratios as well as their complements, such as 3:1, 5:2, 7:3 and 8:5. In general, the disclosed implementations can be applied and adjusted to achieve any arbitrary transformation ratio.

The piezoelectric resonator transformers of FIGS. 1-10 include patterns of metal electrodes in the upper and lower conductive layers that, when provided one or more electrical input signals, cause the piezoelectric layers to have a motional response. The motional response can include a vibrational oscillation along one or more of the X, Y and Z axes. The resonant frequency response of the transformers can be controlled according to a periodic arrangement of the electrodes in the conductive layers, for instance, by adjusting the width(s) as well as the spacing(s) of the electrodes from one another in a conductive layer, such as along the X axis as further explained below.

In FIGS. 1-10, the pattern of interdigitated first electrodes, second, third, and fourth electrodes of the respective conductive layers can be periodic in one direction, for instance, along the X axis. As illustrated, the periodic arrangement of electrodes includes alternating areas of metal, representing electrode regions, and space regions, i.e., areas without metal. Such space regions between the electrodes are also referred to herein as “spaces.” In various implementations, the areas of metal and the spaces have the same width, the areas of metal are wider than the spaces, the areas of metal are narrower than the spaces, or any other appropriate relation between the metal widths and spaces. The finger width of the resonator, a parameter based on a combination of electrode width and spacing, can be adjusted to control one or more resonant frequencies of the structure. For instance, a first finger width in a conductive layer can correspond to a first resonant frequency, and a second finger width in the conductive layer can provide a different second resonant frequency.

The fundamental frequency for the displacement of the piezoelectric layer can be set in part lithographically by the planar dimensions of the upper electrodes, the lower electrodes, and/or the piezoelectric layer. At the device resonant frequency, the electrical signal across the device is reinforced and the device behaves as an electronic resonant circuit. For instance, the piezoelectric resonator transformers described above can be implemented by patterning the input electrodes and output electrodes of a respective conductive layer symmetrically.

The total width, length, and thickness of the piezoelectric resonator transformer are parameters that also can be designated to optimize performance. In some implementations, the finger width of the resonator is the main parameter that is controlled to adjust the resonant frequency of the structure, while the total width multiplied by the total length of the resonator (total area) can be set to control the impedance of the piezoelectric resonator transformer. In one example, the lateral dimensions, i.e., the total width and length of the piezoelectric resonator transformer can be on the order of several 100 μm by several 100 μm for a device designed to operate around 1 GHz (the finger width can be a few microns for 1 GHz operation in case of AlN as the piezoelectric material). In another example, the lateral dimensions are several 100 μm by several 100 μm for a device designed to operate at around 10 MHz. A suitable thickness of the piezoelectric layer 102 can be about 0.01 to 10 μm thick.

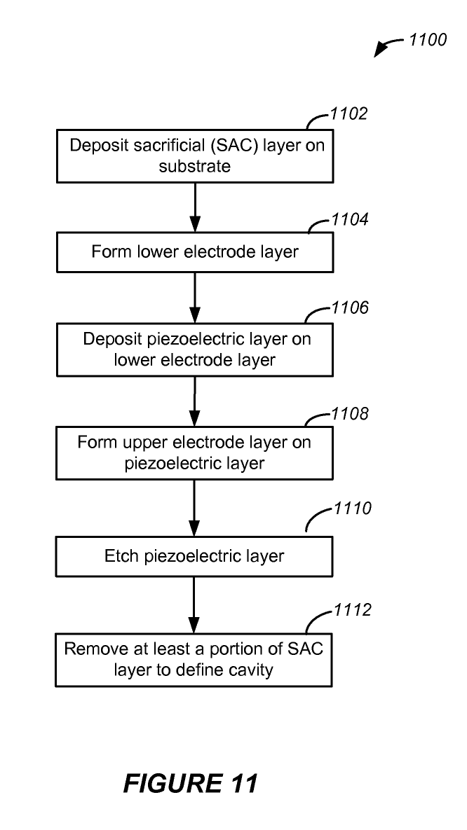

FIG. 11 shows a flow diagram illustrating an example process for forming an example piezoelectric resonator transformer. In one example, the piezoelectric resonator transformer is the piezoelectric transformer 300 shown in FIG. 3. In FIG. 11, process 1100 begins in block 1102 in which a sacrificial (SAC) layer is deposited on a substrate. The SAC layer can have various shapes and sizes, and can be shaped to cover all or some portion of the substrate, depending on the desired implementation. In block 1104, a lower electrode layer is formed on the SAC layer. The lower electrode layer is made of a conductive material such as metal and can be patterned to define two or more sets of electrodes (e.g., third and fourth electrodes 116 and 118), depending on the desired configuration. When more than one electrode is defined, the electrodes can be connected at separate ports of the resonator device. In block 1106, a piezoelectric layer (such as piezoelectric layer 102) is deposited on the lower electrode layer. In block 1108, an upper electrode layer is then formed on the piezoelectric layer. The upper electrode layer also can be patterned to define more than one electrode or set of electrodes (such as first and second electrodes 112 and 114). In some implementations, overlaying groups of electrodes can be defined in the upper and lower electrode layers on opposite surfaces of the upper and lower piezoelectric layers. In some implementations, the piezoelectric layer is then etched or otherwise patterned in block 1110 so as to define a desired resonator geometry and to provide access to the SAC layer. In block 1112, part or all of the SAC layer is removed to define a cavity beneath the piezoelectric resonator transformer.

The piezoelectric materials that can be used in fabrication of the piezoelectric layers of electromechanical systems resonators disclosed herein include, for example, aluminum nitride (AlN), zinc oxide (ZnO), gallium arsenide (GaAs), aluminum gallium arsenide (AlGaAs), gallium nitride (GaN), quartz and other piezoelectric materials such as zinc-sulfide (ZnS), cadmium-sulfide (CdS), lithium tantalite (LiTaO3), lithium niobate (LiNbO3), lead zirconate titanate (PZT), members of the lead lanthanum zirconate titanate (PLZT) family, doped aluminum nitride (AlN:Sc), and combinations thereof. The conductive layers described above may be made of various conductive materials including platinum (Pt), aluminum (Al), molybdenum (Mo), tungsten (W), titanium (Ti), niobium (Nb), ruthenium (Ru), chromium (Cr), doped polycrystalline silicon, doped aluminum gallium arsenide (AlGaAs) compounds, gold (Au), copper (Cu), silver (Ag), tantalum (Ta), cobalt (Co), nickel (Ni), palladium (Pd), silicon germanium (SiGe), doped conductive zinc oxide (ZnO), and combinations thereof. In various implementations, the upper metal electrodes and/or the lower metal electrodes can include the same conductive material(s) or different conductive materials.

Upper and lower conductive layers 104 and 108 can be formed of aluminum (Al), Al/titanium nitride (TiN)/Al, aluminum copper (AlCu), Mo, or other appropriate materials, and have a thickness of 750 to 3000 Angstroms depending on the desired implementation. In some cases, one or both of the conductive layers 104 and 108 is deposited as a bi-layer with a metal such as Mo deposited on top of a seed layer such as AlN. An appropriate thickness for the seed layer can be, for example, 100 to 1000 Angstroms. When Mo is used, the total thickness of the metal layer 1816 can be about 3000 Angstroms. Other suitable materials for conductive layers 104 and 108 include aluminum silicon (AlSi), AlCu, Ti, TiN, Al, platinum (Pt), nickel (Ni), tungsten (W), ruthenium (Ru), and combinations thereof. Thicknesses can range from about 0.1 μm to about 0.3 μm, depending on the desired implementation.

The description herein is directed to certain implementations for the purposes of describing the innovative aspects of this disclosure. However, a person having ordinary skill in the art will readily recognize that the teachings herein can be applied in a multitude of different ways. The described implementations may be implemented in any device or system that can be configured to display an image, whether in motion (e.g., video) or stationary (e.g., still image), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (i.e., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS), microelectromechanical systems (MEMS) and non-MEMS applications), aesthetic structures (e.g., display of images on a piece of jewelry) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the IMOD. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

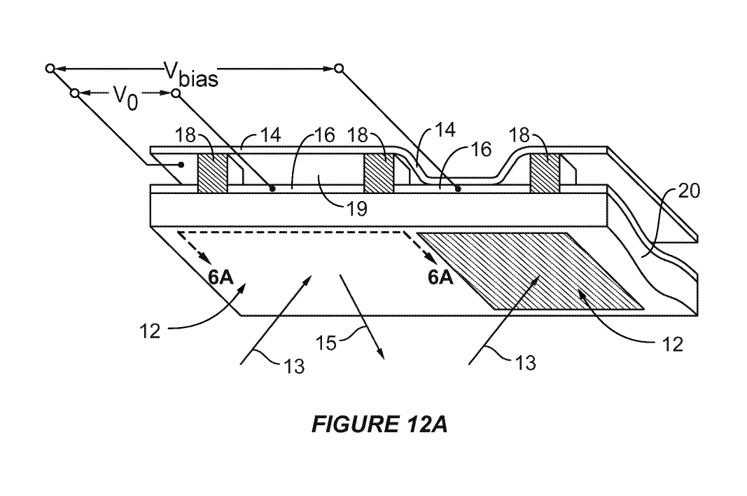

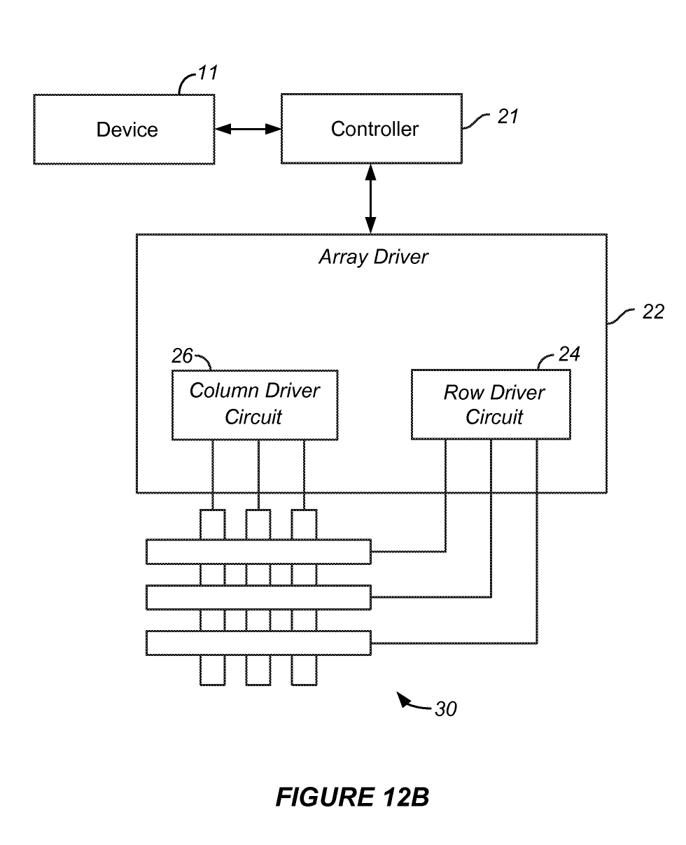

FIG. 12A shows an example of an isometric view depicting two adjacent pixels in a series of pixels of an IMOD display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (such as infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 12A includes two adjacent IMODs 12. In the IMOD 12 on the left (as illustrated), a movable reflective layer 14 is illustrated in a relaxed position at a predetermined distance from an optical stack 16, which includes a partially reflective layer. The voltage V0 applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage Vbias applied across the IMOD 12 on the right is sufficient to maintain the movable reflective layer 14 in the actuated position.

In FIG. 12A, the reflective properties of pixels 12 are generally illustrated with arrows 13 indicating light incident upon the pixels 12, and light 15 reflecting from the IMOD 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the IMOD 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the separation between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the IMOD 12 on the left in FIG. 12A, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated IMOD 12 on the right in FIG. 12A. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 12B shows an example of a system block diagram illustrating an electronic device incorporating a 3×3 IMOD display. The electronic device of FIG. 12B represents one implementation in which a piezoelectric resonator transformer constructed in accordance with the implementations described above with respect to FIGS. 1-10 can be incorporated. The electronic device in which device 11 is incorporated may, for example, form part or all of any of the variety of electrical devices and electromechanical systems devices set forth above, including both display and non-display applications.

Here, the electronic device includes a controller 21, which may include one or more general purpose single- or multi-chip microprocessors such as an ARM®, Pentium®, 8051, MIPS®, Power PC®, or ALPHA®, or special purpose microprocessors such as a digital signal processor, microcontroller, or a programmable gate array. Controller 21 may be configured to execute one or more software modules. In addition to executing an operating system, the controller 21 may be configured to execute one or more software applications, including a web browser, a telephone application, an email program, or any other software application.

The controller 21 is configured to communicate with device 11. The controller 21 also can be configured to communicate with an array driver 22. The array driver 22 can include a row driver circuit 24 and a column driver circuit 26 that provide signals to, e.g., a display array or panel 30. Although FIG. 12B illustrates a 3×3 array of IMODs for the sake of clarity, the display array 30 may contain a very large number of IMODs, and may have a different number of IMODs in rows than in columns, and vice versa. Controller 21 and array driver 22 may sometimes be referred to herein as being “logic devices” and/or part of a “logic system.”

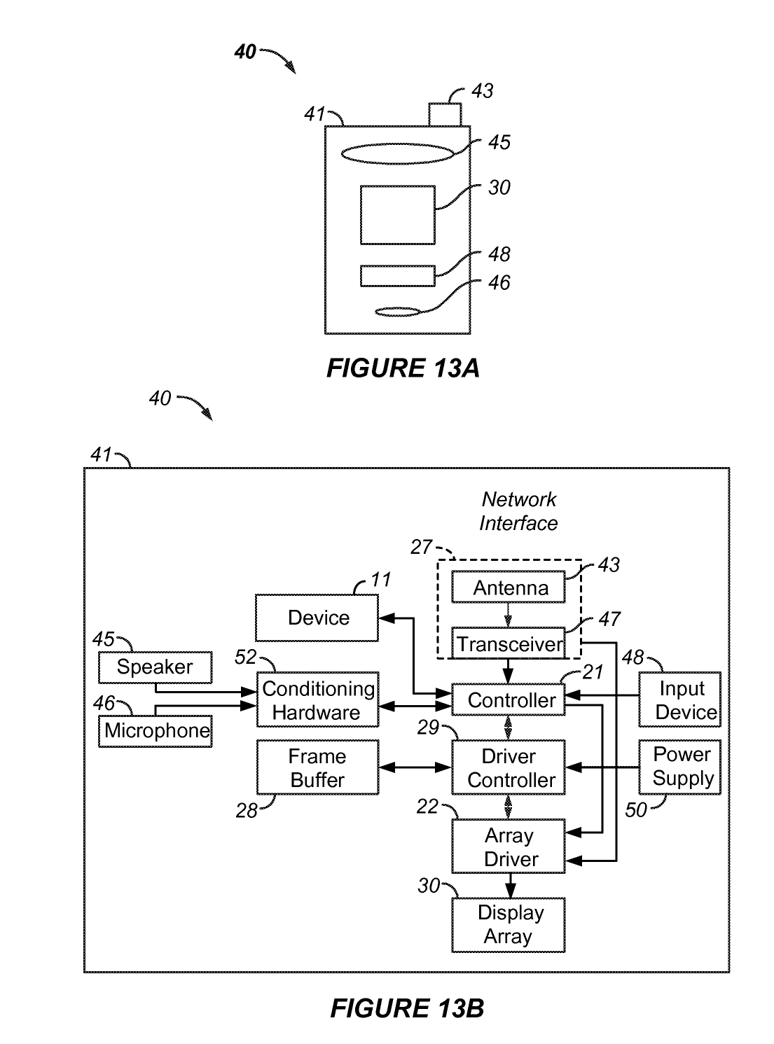

FIGS. 13A and 13B show examples of system block diagrams illustrating a display device 40 that includes a plurality of IMODs. The display device 40 can be, for example, a smart phone, a cellular or mobile telephone. However, the same components of the display device 40 or slight variations thereof are also illustrative of various types of display devices such as televisions, tablets, e-readers, hand-held devices and portable media players.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an IMOD display, as described herein.

The components of the display device 40 are schematically illustrated in FIG. 13B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (such as an IMOD controller). Additionally, the array driver 22 can be a conventional driver or a bi-stable display driver (such as an IMOD display driver). Moreover, the display array 30 can be a conventional display array or a bi-stable display array (such as a display including an array of IMODs). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A piezoelectric transformer comprising:
a piezoelectric layer;
a first conductive layer arranged over a first surface of the piezoelectric layer and including a first set of one or more electrodes and a second set of one or more electrodes, the first set being interdigitated with the second set;
a second conductive layer arranged over a second surface of the piezoelectric layer opposite the first surface and including at least a third set of one or more electrodes;
a first port capable of receiving an input signal, the first set of electrodes being coupled to the first port; and
a second port capable of being coupled to a load and capable of outputting an output signal, the second set of electrodes being coupled to the second port;
wherein a ratio of the number of electrodes of the second set to the number of electrodes of the first set characterizes a transformation ratio.

2. The piezoelectric transformer of claim 1, wherein:
an output impedance is measureable at the second port;
an input impedance is measureable at the first port;
an impedance ratio of the transformer is a ratio of the output impedance to the input impedance; and
the transformation ratio is related to the impedance ratio.

3. The piezoelectric transformer of claim 1, wherein the first conductive layer further includes one or more floating electrodes interdigitated with at least ones of the electrodes of the first and second sets.

4. The piezoelectric transformer of claim 1, wherein the ratio of the number of electrodes of the second set to the number of electrodes of the first set is 1:2.

5. The piezoelectric transformer of claim 4, wherein there are two second set electrodes and four first set electrodes, the second set electrodes being interdigitated with the first set electrodes such that each second set electrode is arranged between two adjacent first set electrodes.

6. The piezoelectric transformer of claim 1, wherein:
the ratio of the number of second set electrodes to the number of first set electrodes is 1:2;
there are four second set electrodes and eight first set electrodes, the second set electrodes being interdigitated with the first set electrodes such that each second set electrode is arranged between two adjacent first set electrodes;
there is a second piezoelectric transformer that includes:
a piezoelectric layer;
a first conductive layer arranged over a first surface of the piezoelectric layer and including a first set of one or more electrodes and a second set of one or more electrodes, the first set being interdigitated with the second set;
a second conductive layer arranged over a second surface of the piezoelectric layer opposite the first surface and including at least a third set of one or more electrodes;
a third port capable of receiving the first output signal from the second port, the first set electrodes of the second piezoelectric transformer being coupled to the third port; and
a fourth port capable of outputting a second output signal, the second set electrodes of the second piezoelectric transformer being coupled to the fourth port;
wherein the ratio of the number of second set electrodes of the second piezoelectric transformer to the number of first set electrodes of the second piezoelectric transformer is 1:2; and
wherein there are two second set electrodes in the second piezoelectric transformer and four first set electrodes in the second piezoelectric transformer, the second set electrodes of the second piezoelectric transformer being interdigitated with the first set electrodes of the second piezoelectric transformer such that each second set electrode is arranged between two adjacent first set electrodes; and
an effective transformation ratio of the combination of the first and second piezoelectric transformers between the fourth port and the first port is about 1:4.

7. The piezoelectric transformer of claim 6, wherein:
there is a third piezoelectric transformer that includes:
a piezoelectric layer;
a first conductive layer arranged over a first surface of the piezoelectric layer and including a first set of one or more electrodes and a second set of one or more electrodes, the first set being interdigitated with the second set;
a second conductive layer arranged over a second surface of the piezoelectric layer opposite the first surface and including at least a third set of one or more electrodes;
a fifth port capable of receiving the second output signal from the fourth port, the first set electrodes of the third piezoelectric transformer being coupled to the fifth port; and
a sixth port capable of outputting a third output signal, the second set electrode of the third piezoelectric transformer being coupled to the sixth port;
wherein the ratio of the number of second set electrodes of the third piezoelectric transformer to the number of first set electrodes of the third piezoelectric transformer is 1:2; and
wherein there is one second set electrode in the third piezoelectric transformer and two first set electrodes in the third piezoelectric transformer, the second set electrodes of the third piezoelectric transformer being interdigitated with the first set electrodes of the third piezoelectric transformer such that the second set electrode is arranged between two adjacent first set electrodes; and
an effective transformation ratio of the combination of the first, second, and third piezoelectric transformers between the sixth port and the first port is about 1:8.

8. The piezoelectric transformer of claim 1, further comprising:
a display;
a processor configured to communicate with the display, the processor being configured to process image data; and
a memory device configured to communicate with the processor.

9. The piezoelectric transformer of claim 1, further comprising:
a driver circuit configured to send at least one signal to the display; and
a controller configured to send at least a portion of the image data to the driver circuit.

10. The piezoelectric transformer of claim 1, wherein one or more of the electrodes are coupled to send the image data to the processor.

11. A piezoelectric transformer comprising:
a piezoelectric layer;
a first conductive layer arranged over a first surface of the piezoelectric layer and including a first set of one or more electrodes and a second set of one or more electrodes; and
a second conductive layer arranged over a second surface of the piezoelectric layer opposite the first surface and including a third set of one or more electrodes and a fourth set of one or more electrodes;
wherein:
the first set of electrodes and the third set of electrodes are arranged in a first arrangement, the first arrangement including a number of first pairs, each first pair including an electrode from the first set and a corresponding electrode from the third set;
the second set of electrodes and the fourth set of electrodes are arranged in a second arrangement, the second arrangement including a number of second pairs, each second pair including an electrode from the second set and a corresponding electrode from the fourth set;
the first arrangement is interdigitated with the second arrangement; and
a ratio of the number of second pairs to the number of first pairs at least partially characterizes a transformation ratio.

12. The piezoelectric transformer of claim 11, further comprising:
a first input port capable of receiving a first component of a differential input signal, the first set of electrodes being coupled to the first input port;
a second input port capable of receiving a second component of the differential input signal, the third set of electrodes being coupled to the second input port;
a first output port capable of being coupled to a load and capable of outputting a first component of a differential output signal, the second set of electrodes being coupled to the first output port; and
a second output port capable of being coupled to the load and capable of outputting a second component of the differential output signal, the fourth set of electrodes being coupled to the second output port.

13. The piezoelectric transformer of claim 12, wherein:
an output impedance is measureable at the output ports;
an input impedance is measureable at the drive ports;
an impedance ratio of the transformer is a ratio of the output impedance to the input impedance; and
the transformation ratio is related to the impedance ratio.

14. The piezoelectric transformer of claim 11, wherein one or both of the first conductive layer and the second conductive layer further includes one or more floating electrodes.

15. The piezoelectric transformer of claim 11, wherein the ratio of the number of second pairs to the number of first pairs is 1:2.

16. The piezoelectric transformer of claim 15, wherein there are two second pairs and four first pairs, the second pairs being interdigitated with the first pairs such that each second pair is arranged between two adjacent first pairs.

17. The piezoelectric transformer of claim 16, wherein:
the first pairs include four first pairs;
the second pairs include two second pairs;
the first second pair is arranged between the first and second first pairs;
the second second pair is arranged between the third and fourth first pairs; and
the piezoelectric transformer further includes a pair of floating electrodes arranged between the second and third first pairs.

18. The piezoelectric transformer of claim 15, wherein:
the first pairs include eight first pairs;
the second pairs include four second pairs;
the piezoelectric transformer further includes a first pair of floating electrodes, a second pair of floating electrodes, and a third pair of floating electrodes;
a first second pair is arranged between the first and second first pairs;
a second second pair is arranged between the third and the fourth first pairs;
a third second pair is arranged between the fifth and sixth first pairs;
a fourth second pair is arranged between the seventh and eighth first pairs;
the first pair of floating electrodes is arranged between the second and third first pairs;
the second pair of floating electrodes is arranged between the fourth and fifth first pairs; and
the third pair of floating electrodes is arranged between the sixth and seventh first pairs.

19. The piezoelectric transformer of claim 11, wherein:
the ratio of the number of second pairs to the number of first pairs is 1:2;
there are four second pairs and eight first pairs, the second pairs being interdigitated with the first pairs such that each second pair is arranged between two adjacent first pairs;
the piezoelectric transformer further includes:
a first input port capable of receiving a first component of a differential input signal, the first set of electrodes being coupled to the first input port;
a second input port capable of receiving a second component of the differential input signal, the third set of electrodes being coupled to the second input port;
a first output port capable of outputting a first component of a first differential output signal, the second set of electrodes being coupled to the first output port; and
a second output port capable of outputting a second component of the first differential output signal, the fourth set of electrodes being coupled to the second output port;
there is a second piezoelectric transformer that includes:
a piezoelectric layer;
a first conductive layer arranged over a first surface of the piezoelectric layer and including a first set of one or more electrodes and a second set of one or more electrodes; and
a second conductive layer arranged over a second surface of the piezoelectric layer opposite the first surface and including a third set of one or more electrodes and a fourth set of one or more electrodes;
wherein:
the first set of electrodes and the third set of electrodes are arranged in a first arrangement, the first arrangement including a number of first pairs, each first pair including an electrode from the first set and a corresponding electrode from the third set;
the second set of electrodes and the fourth set of electrodes are arranged in a second arrangement, the second arrangement including a number of second pairs, each second pair including an electrode from the second set and a corresponding electrode from the fourth set;
the ratio of the number of second pairs of the second piezoelectric transformer to the number of first pairs of the second piezoelectric transformer is 1:2;
there are two second pairs in the second piezoelectric transformer and four first pairs in the second piezoelectric transformer, the second pairs of the second piezoelectric transformer being interdigitated with the first pairs of the second piezoelectric transformer such that each second pair is arranged between two adjacent first pairs;
there is a third input port capable of receiving the first component of the first differential output signal, the first set of electrodes of the second piezoelectric transformer being coupled to the third input port;
there is a fourth input port capable of receiving the second component of the first differential output signal, the third set of electrodes of the second piezoelectric transformer being coupled to the fourth input port;
there is a third output port capable of outputting a first component of a second differential output signal, the second set of electrodes of the second piezoelectric transformer being coupled to the third output port; and
there is a fourth output port capable of outputting a second component of the second differential output signal, the fourth set of electrodes of the second piezoelectric transformer being coupled to the fourth output port; and
an effective transformation ratio of the combination of the first and second piezoelectric transformers between the third and fourth output ports and the first and second input ports is substantially 1:4.

20. The piezoelectric transformer of claim 19, wherein:
there is a third piezoelectric transformer that includes:
a piezoelectric layer;
a first conductive layer arranged over a first surface of the piezoelectric layer and including a first set of one or more electrodes and a second set of one or more electrodes; and
a second conductive layer arranged over a second surface of the piezoelectric layer opposite the first surface and including a third set of one or more electrodes and a fourth set of one or more electrodes;
wherein:
the first set of electrodes and the third set of electrodes are arranged in a first arrangement, the first arrangement including a number of first pairs, each first pair including an electrode from the first set and a corresponding electrode from the third set;
the second set of electrodes and the fourth set of electrodes are arranged in a second arrangement, the second arrangement including a number of second pairs, each second pair including an electrode from the second set and a corresponding electrode from the fourth set;
the ratio of the number of second pairs of the third piezoelectric transformer to the number of first pairs of the third piezoelectric transformer is 1:2;
there is one second pair in the third piezoelectric transformer and two first pairs in the third piezoelectric transformer, the second pairs of the third piezoelectric transformer being interdigitated with the first pairs of the third piezoelectric transformer such that the second pair is arranged between two adjacent first pairs;
there is a fifth input port capable of receiving the first component of the second differential output signal, the first set of electrodes of the third piezoelectric transformer being coupled to the fifth input port;
there is a sixth input port capable of receiving the second component of the second differential output signal, the third set of electrodes of the third piezoelectric transformer being coupled to the sixth input port;
there is a fifth output port capable of outputting a first component of a third differential output signal, the second set of electrodes of the third piezoelectric transformer being coupled to the fifth output port; and
there is a sixth output port capable of outputting a second component of the third differential output signal, the fourth set of electrodes of the third piezoelectric transformer being coupled to the sixth output port;
an effective transformation ratio of the combination of the first, second, and third piezoelectric transformers between the fifth and sixth output ports and the first and second input ports is substantially 1:8.

21. The piezoelectric transformer of claim 11, further comprising:
a fifth set of electrodes in the first conductive layer;
a sixth set of electrodes in the second conductive layer;
wherein:
the fifth set of electrodes and the sixth set of electrodes are arranged in a third arrangement, the third arrangement including a number of third pairs, each third pair comprising an electrode from the fifth set and a corresponding electrode from the sixth set;
the third arrangement is interdigitated with the first and second arrangements; and
a ratio of the sum of the number of second pairs and the number of third pairs to the number of first pairs characterizes an effective transformation ratio;
a first input port capable of receiving a differential input signal, the first set of electrodes being coupled to the first input port;
a second input port capable of receiving the differential input signal, the sixth set of electrodes being coupled to the second input port;
a first output port capable of being coupled to a load and capable of outputting an output signal, the second set of electrodes being coupled to the first output port; and
one or more ground ports, each of the second set of electrodes, the fifth set of electrodes, and the fourth set of electrodes being coupled to one or more of the ground ports.

22. The piezoelectric transformer of claim 11 further comprising:
a display;
a processor configured to communicate with the display, the processor being configured to process image data; and
a memory device configured to communicate with the processor.

23. The piezoelectric transformer of claim 11, further comprising:
a driver circuit configured to send at least one signal to the display; and
a controller configured to send at least a portion of the image data to the driver circuit.

24. The piezoelectric transformer of claim 11, wherein one or more of the electrodes are coupled to send the image data to the processor.

25. A piezoelectric transformer comprising:
a first resonator including:
an upper conductive layer,
a lower conductive layer, and
a piezoelectric layer disposed between the upper conductive layer and the lower conductive layer,
one or more of the conductive layers including a plurality of input electrodes and one or more output electrodes, the input electrodes coupled to an input port capable of receiving a differential signal, the one or more output electrodes coupled to a connection port; and
a second resonator including:
an upper conductive layer,
a lower conductive layer, and
a piezoelectric layer disposed between the upper conductive layer and the lower conductive layer of the second resonator,
one or more of the conductive layers of the second resonator including a plurality of input electrodes and one or more output electrodes, the input electrodes of the second resonator coupled to the connection port, the one or more output electrodes of the second resonator coupled to an output port capable of being coupled to a load;
a number of the output electrodes of the second resonator in relation to a number of the input electrodes of the first resonator defining a transformation ratio.

26. The piezoelectric transformer of claim 25, wherein one or both of the upper conductive layer and the lower conductive layer of one or both of the first resonator and the second resonator further includes one or more floating electrodes.

27. A process for forming a resonator structure, comprising:
forming a lower conductive layer of electrodes;
forming a piezoelectric layer over the lower electrode layer; and
forming an upper conductive layer of electrodes over the piezoelectric layer;
wherein:
the upper conductive layer including at least a first set of one or more electrodes and a second set of one or more electrodes, the first set being interdigitated with the second set;
the lower conductive layer including at least a third set of one or more electrodes; and
a ratio of the number of electrodes of the second set to the number of electrodes of the first set characterizes a transformation ratio.

28. The process of claim 27, wherein:
the lower conductive layer further includes a fourth set of one or more electrodes;
the first set of electrodes and the third set of electrodes are arranged in a first arrangement, the first arrangement including a number of first pairs, each first pair including an electrode from the first set and a corresponding electrode from the third set;
the second set of electrodes and the fourth set of electrodes are arranged in a second arrangement, the second arrangement including a number of second pairs, each second pair including an electrode from the second set and a corresponding electrode from the fourth set;
the first arrangement is interdigitated with the second arrangement; and
a ratio of the number of second pairs to the number of first pairs at least partially characterizes a transformation ratio.

29. The process of claim 27, wherein:
the upper conductive layer further includes a fifth set of electrodes;
the lower conductive layer further includes a sixth set of electrodes;
wherein:
the fifth set of electrodes and the sixth set of electrodes are arranged in a third arrangement, the third arrangement including a number of third pairs, each third pair comprising an electrode from the fifth set and a corresponding electrode from the sixth set;
the third arrangement is interdigitated with the first and second arrangements; and
a ratio of the sum of the number of second pairs and the number of third pairs to the number of first pairs characterizes an effective transformation ratio.

30. A piezoelectric transformer comprising:
piezoelectric means including piezoelectric material;
first conductive means arranged over a first surface of the piezoelectric material and including a first set of one or more electrodes and a second set of one or more electrodes, the first set being interdigitated with the second set;
second conductive means arranged over a second surface of the piezoelectric material opposite the first surface and including at least a third set of one or more electrodes;
first coupling means capable of receiving an input signal, the first set of electrodes being coupled to the first coupling means; and
second coupling means capable of being coupled to a load and capable of outputting an output signal, the second set of electrodes being coupled to the second coupling means;
wherein a ratio of the number of electrodes of the second set to the number of electrodes of the first set characterizes a transformation ratio.

31. The piezoelectric transformer of claim 30, wherein:
the second conductive means further includes a fourth set of one or more electrodes;
the first set of electrodes and the third set of electrodes are arranged in a first arrangement, the first arrangement including a number of first pairs, each first pair including an electrode from the first set and a corresponding electrode from the third set;
the second set of electrodes and the fourth set of electrodes are arranged in a second arrangement, the second arrangement including a number of second pairs, each second pair including an electrode from the second set and a corresponding electrode from the fourth set;
the first arrangement is interdigitated with the second arrangement; and
a ratio of the number of second pairs to the number of first pairs at least partially characterizes a transformation ratio.

32. The piezoelectric transformer of claim 30, wherein:
the first conductive means further includes a fifth set of electrodes;
the second conductive means further includes a sixth set of electrodes;
wherein:
the fifth set of electrodes and the sixth set of electrodes are arranged in a third arrangement, the third arrangement including a number of third pairs, each third pair comprising an electrode from the fifth set and a corresponding electrode from the sixth set;
the third arrangement is interdigitated with the first and second arrangements; and
a ratio of the sum of the number of second pairs and the number of third pairs to the number of first pairs characterizes an effective transformation ratio.
